(19) United States
(12) Patent Application Publication
(10) Pub. No.: US 2025/0203889 A1
(43) Pub. Date: Jun. 19, 2025

(54) SILICON SUBSTRATE SEMICONDUCTOR PACKAGE WITH INTEGRATED STACK CAPACITOR AND METHOD OF MANUFACTURING THE SAME

(71) Applicant: SAMSUNG ELECTRONICS CO., LTD., Suwon-si (KR)

(72) Inventors: Yan LI, Santa Clara, CA (US); WooPoung Kim, San Jose, CA (US)

(73) Assignee: SAMSUNG ELECTRONICS CO., LTD., Suwon-si (KR)

(21) Appl. No.: 18/912,036

(22) Filed: Oct. 10, 2024

Related U.S. Application Data
(60) Provisional application No. 63/611,535, filed on Dec. 18, 2023.

(51) Int. Cl. H01L 21/48; H01L 23/00; H01L 23/14; H01L 23/538; H01L 25/16

(52) U.S. Cl. CPC H10D 1/68; H01L 21/4857; H01L 23/147; H01L 23/5383; H01L 25/16; H01L 24/16; H01L 2224/16225

(57) ABSTRACT

Provided is a semiconductor package including a silicon substrate including a through-silicon via, a first build-up layer on a first surface of the silicon substrate, a second build-up layer on a second surface of the silicon substrate, and at least one integrated stack capacitor included in at least one of the silicon substrate, the first build-up layer, and the second build-up layer.

### CROSS-REFERENCE TO THE RELATED APPLICATION

This application is based on and claims benefit to U.S. Provisional Application No. 63/611,535 filed on Dec. 18, 2023 in the U.S. Patent and Trademark Office, the disclosure of which is incorporated herein in its entirety by reference.

### BACKGROUND

### 1. Field

Embodiments of the present disclosure relate to a method of manufacturing a semiconductor package with a silicon interposer and integrated stack capacitors (ISC) and an apparatus thereof.

### 2. Description of Related Art

As the electronic devices are becoming smaller, a semiconductor package used in the electronic devices also needs to become smaller and have a high reliability together with high performance and high capacity. Accordingly, the importance of the structure of the semiconductor package for responding to the size and performance of the semiconductor package and more stably supplying power to the semiconductor package is increasing.

Information disclosed in this Background section has already been known to the inventors before achieving the disclosure of the present application or is technical information acquired in the process of achieving the disclosure. Therefore, it may contain information that does not form the prior art that is already known to the public.

### SUMMARY

One or more embodiments provide a method of manufacturing a semiconductor package with a silicon interposer and an integrated stack capacitor, and an apparatus thereof.

One or more embodiments provide a semiconductor package including an integrated stack capacitor with a relatively small size to reduce the vertical size and improve the power distribution network (PDN) and signal integration of the semiconductor device.

According to an aspect of an embodiment, there is provided a semiconductor package including a silicon substrate including a through-silicon via, a first build-up layer on a first surface of the silicon substrate, a second build-up layer on a second surface of the silicon substrate, and at least one capacitor included in at least one of the silicon substrate, the first build-up layer, and the second build-up layer.

According to another aspect of an embodiment, there is provided a method of manufacturing a semiconductor package, the method including providing a silicon substrate including through-silicon via, providing a first build-up layer on a first surface of the silicon substrate, providing a second build-up layer on an second surface of the silicon substrate, providing a capacitor in at least one of the silicon substrate, the first build-up layer, and the second build-up layer, and providing a semiconductor chip.

According to another aspect of an embodiment, there is provided an electronic system including at least one memory configured to store computer-readable instructions and a plurality of data, and at least one processor configured to execute the computer-readable instructions and implement a plurality of computing operations using the plurality of data, wherein the at least one processor includes a semiconductor package including a silicon substrate including a through-silicon via, a first build-up layer on a first surface of the silicon substrate, a second build-up layer on a second surface of the silicon substrate, and at least one capacitor included in at least one of the silicon substrate, the first build-up layer, and the second build-up layer.

### BRIEF DESCRIPTION OF DRAWINGS

The above and/or other aspects, features, and advantages of one or more embodiments of the disclosure will be more apparent from the following description taken in conjunction with the accompanying drawings, in which:

FIG. 1 illustrates a semiconductor package according to one or more embodiments;

FIG. 2A illustrates a cross-sectional view of providing a laser groove on a silicon substrate, FIG. 2B illustrates a cross-sectional view of providing one or more ISCs on the groove, FIG. 2C illustrates a cross-sectional view of providing a build-up insulating layer on the silicon substrate and grooves, FIG. 2D illustrates a cross-sectional view of providing through-silicon tunnels, and FIG. 2E illustrates a cross-sectional view of providing metal materials in the through-silicon tunnels to form through-silicon vias in a semiconductor package according to one or more embodiments;

FIG. 3A illustrates a cross-sectional view of providing a silicon substrate with through-silicon vias, FIG. 3B illustrates a cross-sectional view of providing one or more ISCs, FIG. 3C illustrates a cross-sectional view of providing build-up insulating layers on the silicon substrate, and FIG. 3D illustrate cross-sectional view of providing vias on the build-up insulating layers in a semiconductor package according to one or more other embodiments;

FIG. 4A illustrates an enlarged cross-sectional view of area A in FIG. 3D and FIG. 4B illustrates an enlarged cross-sectional view of area B in FIG. 3D;

FIG. 5A illustrates a cross-sectional view of providing a silicon substrate with through-silicon vias, FIG. 5B illustrates a cross-sectional view of providing one or more ISCs, FIG. 5C illustrates a cross-sectional view of providing build-up insulating layers on the silicon substrate, and FIG. 5D illustrate cross-sectional view of providing vias on the build-up insulating in a semiconductor package according to another embodiment;

FIG. 6A illustrates an enlarged cross-sectional view of area C in FIG. 5D and FIG. 6B illustrates an enlarged cross-sectional view of area D in FIG. 5D;

FIG. 7 illustrates a semiconductor package according to one or more other embodiments;

FIG. 8 illustrates a semiconductor package according to one or more other embodiments;

FIG. 9 illustrates a semiconductor package according to one or more other embodiments;

FIG. 10 illustrates a semiconductor package according to one or more other embodiments;

FIG. 11 illustrates a semiconductor package according to one or more other embodiments;

FIG. 12 illustrates a flowchart of a method of manufacturing a semiconductor package according to one or more embodiments;

FIG. 13 illustrates a semiconductor package architecture that may incorporate the semiconductor packages according to one or more embodiments; and

FIG. 14 illustrates a schematic block diagram of an electronic system according to one or more embodiments.

### DETAILED DESCRIPTION

The embodiments described herein are examples, and thus, the present disclosure is not limited thereto, and may be realized in various other forms. Each of the embodiments provided in the following description is not excluded from being associated with one or more features of another example or one or more other embodiments also provided herein or not provided herein but consistent with the present disclosure. For example, even if matters described in a specific example or embodiment are not described in a different example or embodiment thereto, the matters may be understood as being related to or combined with the different example or embodiment, unless otherwise mentioned in descriptions thereof.

In addition, it should be understood that all descriptions of principles, aspects, examples, and embodiments are intended to encompass structural and functional equivalents thereof. In addition, these equivalents should be understood as including not only currently well-known equivalents but also equivalents to be developed in the future, that is, all devices invented to perform the same functions regardless of the structures thereof.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

Spatially relative terms, such as “over,” “above,” “on,” “upper,” “below,” “under,” “beneath,” “lower,” “top,” and “bottom,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures. For example, if the semiconductor device in the figures is turned over, elements described as “below” or “beneath” other elements would then be oriented “above” the other elements. Thus, the term “below” can encompass both an orientation of above and below. The semiconductor device may be otherwise oriented (rotated 90 degrees or at other orientations) and the spatially relative descriptors used herein interpreted accordingly.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. Herein, when a term “same” is used to compare a dimension of two or more elements, the term may cover a “substantially same” dimension.

It will be understood that, although the terms “first,” “second,” “third,” “fourth,” etc. may be used herein to describe various elements, these elements should not be limited by these terms. These terms are only used to distinguish one element from another element. Thus, a first element discussed below could be termed a second element without departing from the teachings of the present disclosure.

It will be also understood that, even if a certain step or operation of manufacturing an apparatus or structure is described later than another step or operation, the step or operation may be performed later than the other step or operation unless the other step or operation is described as being performed after the step or operation. It will be understood that any of the components or any combination of the components described herein may be used to perform one or more the operations of the flowcharts. Further, all operations are example operations, and may include various additional steps.

Embodiments are described herein with reference to cross-sectional illustrations that are schematic illustrations of the embodiments (and intermediate structures). As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present disclosure. Further, in the drawings, the sizes and relative sizes of layers and regions may be exaggerated for clarity.

For the sake of brevity, general elements to semiconductor devices may or may not be described in detail herein.

Due to the high computing performance demands in various applications such as artificial intelligence (AI) applications, a larger semiconductor package size is required to integrate a greater number of central processing units (CPUs), graphical processing units (GPUs), high bandwidth memories (HBMs), AI chips, etc. in a single semiconductor package. As the thermal design power (TDP) required for CPUs and GPUs increases, a larger package with a relatively low impedance power distribution network (PDN) across multiple frequency ranges, particularly in the high frequency domain, is required.

Silicon (Si) interposers with a through-silicon via (TSV) enable heterogeneous integration of CPUs, GPUs, and HBMs. However, due to the relatively low resistances of silicon (Si) which is about 5-10 Ω·cm, silicon interposers with TSVs may experience signal loss, electromagnetic interference, crosstalk, and coupling issue in the relatively high frequency domain. Additionally, producing packages greater than 100 mm×100 mm may be difficult due to manufactory and cost concerns.

Semiconductor packages according to one or more embodiments provide integrated stack capacitors being embedded in build-up layers, redistribution layers, or grooves of a silicon substrate of the semiconductor package. Accordingly, the vertical size of the semiconductor package and the impedance of the power distribution network (PDN) for multiple frequency ranges, in particular, relatively high frequency ranges, may be reduced to improve performance of the semiconductor package.

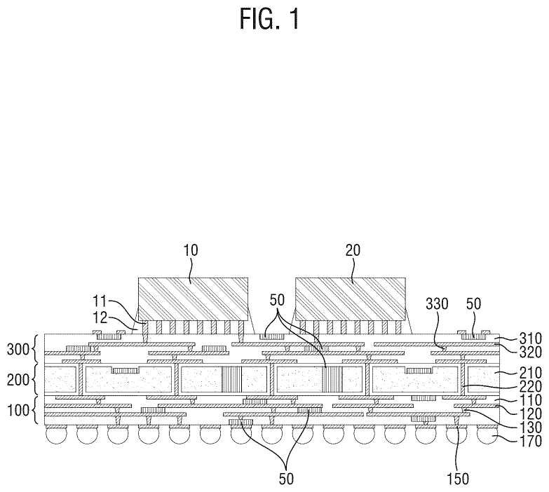

FIG. 1 illustrates a semiconductor package according to one or more embodiments.

Referring to FIG. 1, a semiconductor package 1 may include a first semiconductor chip 10, a second semiconductor chip 20, a first build-up layer 100, a silicon interposer 200, and a second build-up layer 300.

Herein, a direction parallel to a main surface of the first build-up layer 100 may be referred to as a horizontal direction (X direction and/or Y direction), and a direction perpendicular to the horizontal direction (X direction and/or Y direction) and normal to the main surface of the first build-up layer 100 may be referred to as a vertical direction (Z direction).

The first build-up layer 100 may include one or more first build-up insulating layers 110, first wiring patterns 120, and first through vias 130. The first wiring patterns 120 and the first through vias 130 may be included or enclosed in the first build-up insulating layers 110. The first build-up insulating layer 110 may include an organic insulating material, such as an Ajinomoto build-up film (ABF), oxide, nitride, a photo-imageable dielectric (PID) resin prepared by combining epoxy resin and photoinitiators, and may further include photosensitive polyimide and/or inorganic fillers, etc. However, embodiments are not limited thereto. For example, in lieu of a build-up layer, a redistribution layer including one or more redistribution insulating layers, wiring patterns, and vias may be provided.

The first wiring patterns 120 and the first through vias 130 may be provided as conductive patterns, and the conductive patterns may be positioned in the first build-up insulating layer 110. The first wiring patterns 120 may extend in the horizontal direction (X direction and/or Y direction) and be provided at different vertical levels within the first build-up insulating layers 110. The first through vias 130 may penetrate one or more first build-up insulating layer 110 in the vertical direction (Z direction), to interconnect the first wiring patterns 120 and electrically connect the first wiring patterns 120.

According to one or more embodiments, at least some of the first wiring patterns 120 may be integrally provided together with some of the first through vias 130. For example, the first wiring patterns 120 and the first through vias 130, that contact each other, may be integrally formed as a single structure.

According to one or more embodiments, the first through vias 130 may have any suitable shape including, for example, a tapered shape in which the horizontal widths of the first through vias 130 decrease in the vertical direction (Z direction) away from the first semiconductor chip 10 and the second semiconductor chip 20 depending on the manufacturing conditions. However, embodiments are not limited thereto.

The first wiring patterns 120 and the first through vias 130 may include, for example, metals such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and an alloy thereof, but is not limited thereto.

The semiconductor package 1 may further include a passivation layer 140, an under bump metallurgy (UBM) layer 150, and a conductive layer 160. For example, the passivation layer 140 may have a single-layer structure and may be provided on a lower surface of the first build-up insulating layer 110. In another embodiment, the passivation layer 140 may have a multi-layer structure. The passivation layer 140 may at least partially cover an exposed upper surface and a side surface of the conductive layer 160 and may expose a lower surface of the conductive layer 160. In addition, the UBM layers 150 may be provided on a portion of the upper surface of the passivation layer 140.

The passivation layer 140 may include an insulating material, for example, an ABF, silicon oxide, silicon nitride, phosphosilicate glass (PSG), borophosphosilicate glass (BPSG), fluorosilicate glass (FSG), and a combination thereof.

The UBM layer 150 may electrically connect the conductive layer 160 with other components of the semiconductor package 1 such as an external connection terminal 170. In addition, the UBM layer 150 may prevent the external connection terminal 170 from cracking due to the thermal shock between the external connection terminal 170 and the first build-up layer 100, to thereby improve the reliability of the semiconductor package 1. The UBM layer 150 may include a conductive material, for example, copper (Cu), aluminum (Al), silver (Ag), gold (Au), tungsten (W), titanium (Ti), and a combination thereof.

The conductive layer 160 may be provided on the passivation layer 140, and the lower surface of the conductive layer 160 may be exposed from the lower surface of the passivation layer 140. The conductive layer 160 may include conductive patterns that are spaced apart in the first horizontal direction (X direction) or the second horizontal direction (Y direction). In FIG. 1, the conductive layer 160 is shown as single layered conductive patterns that are provided at a single vertical level, however, embodiments are not limited thereto, and the conductive layer 160 may be provided as a multilayered conductive pattern that is provided at different vertical levels depending on embodiments. The conductive layer 160 may include, for example, a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), and an alloy thereof but is not limited thereto.

The external connection terminal 170 may be provided on the lower surface of the UBM layer 150. The external connection terminal 170 may connect the first semiconductor chip 10 and the second semiconductor chip 20 to a device external to the semiconductor package 1 such as, for example, a module substrate, a system board, and a printed circuit board. The external connection terminal 170 may be configured to connect the first build-up layer 100 and an external device electrically and/or physically. According to one or more embodiments, the external connection terminal 170 may include, for example, a solder ball, a conductive bump, and a flip-chip connection structure having a grid array such as a pin grid array, a ball grid array, and a land grid array. The external connection terminal 170 may be electrically connected to the UBM layer 150 and may be electrically connected to the external device such as a module substrate, a system board, and a printed circuit board.

A silicon interposer 200 may be provided on an upper surface of the first build-up layer 100. The silicon interposer 200 may include a silicon substrate 210 and through-silicon vias (TSV) 220 vertically penetrating the silicon substrate 210. As another embodiment, in lieu of the through-silicon via, the silicon interposer 200 may include a through organic via (TOV), a coaxial via (COV), or a copper (Cu) via-in-via.

The through-silicon vias 220 may be provided between the first build-up layer 100 and the second build-up layer 300, and provide an electrical connection path between the first build-up layer 100 and the second build-up layer 300. The through-silicon vias 220 may include a conductive material including, for example, copper (Cu), aluminum (Al), silver (Ag), gold (Au), tungsten (W), titanium (Ti), and a combination thereof.

The through-silicon vias 220 may have an upper surface and a lower surface spaced apart from each other in the vertical direction (Z direction). The upper surface of the through-silicon vias 220 may be coplanar with the upper surface of the silicon substrate 210, and the lower surface of the through-silicon vias 220 may be coplanar with the lower surface of the silicon substrate 210. The through-silicon vias 220 may be at least partially in contact with the first through vias 130 and first wiring patterns 120 exposed on an upper surface of the uppermost first build-up insulating layer 110. For example, the lower surfaces of the through-silicon vias 220 may be bonded and connected to the upper surface of the first through vias 130 and first wiring patterns 120.

Each of the through-silicon vias 220 may have any suitable shape including, for example, a cylindrical shape. The diameter of each of the through-silicon vias 220 in the horizontal direction (X or Y direction) may be constant along the vertical direction (Z direction). In another embodiment, the plurality of through-silicon vias 220 may have tapered shapes having diameters in the horizontal direction (X or Y direction) that vary along the vertical direction (Z direction) depending on the manufacturing conditions.

The second build-up layer 300 may be positioned on the silicon interposer 200. The second build-up layer 300 may include one or more second build-up insulating layers 310, second wiring patterns 320, and second through vias 330. The second wiring patterns 320 and the second through vias 330 may be included or enclosed in the second build-up insulating layers 310. However, embodiments are not limited thereto. For example, in lieu of a build-up layer, a redistribution layer including one or more redistribution insulating layers, wiring patterns, and vias may be provided.

The second build-up insulating layers 310 may be stacked in the vertical direction (Z direction). The second build-up insulating layer 310 may include an insulating material, such as ABF, oxide, and nitride, a photo-imageable dielectric (PID) resin prepared by combining epoxy resin and photoinitiators, and may further include photosensitive polyimide and/or inorganic fillers, etc., not being limited thereto.

The second wiring patterns 320 and the second through vias 330 may be provided as conductive patterns, and the conductive patterns may be positioned in the second build-up insulating layer 310. The second wiring patterns 320 may extend in the horizontal direction (X direction and/or Y direction) and be provided at different vertical levels within the second build-up insulating layers 310. The second through vias 330 may penetrate one or more second build-up insulating layer 310 in the vertical direction (Z direction), to interconnect the second wiring patterns 320 and electrically connect the second wiring patterns 320.

According to embodiments, at least some of the second wiring patterns 320 may be integrally provided together with some of the second through vias 330. For example, the second wiring patterns 320 and the second through vias 330, that contact each other, may be integrally formed as a single and continuous structure without an interface therebetween.

According to embodiments, the second through vias 330 may have any suitable shape including, for example, a tapered shape in which the horizontal widths of the second through vias 330 decrease in the vertical direction (Z direction) away from the first semiconductor chip 10 and the second semiconductor chip 20 depending on the manufacturing conditions.

The second wiring patterns 320 and the second through vias 330 may include, for example, metals such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and an alloy thereof but is not limited thereto.

The first semiconductor chip 10 and the second semiconductor chip 20 may be provided on the upper surface of the second build-up layer 300.

The first semiconductor chip 10 and the second semiconductor chip 20 may be, for example, a high bandwidth memory (HBM) and a system-on-chip (SOC). However, embodiments are not limited thereto, and semiconductor chips other than an SOC or an HBM, such as, for example, a logic chip such as a central processor (CPU), a graphics processor (GPU), a field programmable gate array (FPGA), a digital signal processor (DSP), an application-specific integrated circuit (ASIC) or a memory chip such as a dynamic random access memory (DRAM) chip and a NAND chip, may be provided.

Connection members 11 may be provided between a lower surface of the first semiconductor chip 10 and the upper surface of the second build-up layer 300. The lower surface of the first semiconductor chip 10 may include connection pads. The connection pads of the first semiconductor chip 10 may be electrically connected to the second build-up layer 300 through the connection members 11. An underfill layer 12 may be provided adjacent to and to surround the connection members 11 between the first semiconductor chip 10 and the second build-up layer 300. Connection members 11 may be provided between active lower surface of the second semiconductor chip 20 and the upper surface of the second build-up layer 300. The lower surface of the second semiconductor chip 20 may include connection pads. The connection pads of the second semiconductor chip 20 may be electrically connected to the second build-up layer 300 through the connection members 11. An underfill layer 12 may be provided adjacent to and to surround the connection members 11 between the second semiconductor chip 20 and the second build-up layer 300. The underfill layer 12 may include a slant outer surface. The underfill layer 12 may include an epoxy resin or two or more silicon hybrid materials.

The semiconductor package 1 may further include one or more integrated stack capacitors (ISCs) 50. Each of the one or more ISCs 50 may be a silicon-based ISC 50 including a concave array of capacitive vias respectively having a vertical cylinder shape on a silicon backplane. A thickness in the Z direction of the ISC 50 may range from less than 2 μm to 780 μm. However, embodiments are not limited thereto. For example, a vertical cylinder array may have a size of 2×2 μm², and the ISC 50 may include concave arrays. For example, a value of capacitance of the ISC 50 may be about hundreds of nF/mm². Accordingly, the ISC 50 may have a relatively small size and a relatively high capacitance density, compared to, for example, a multilayer ceramic capacitor (MLCC).

Due to the relatively small size of the ISC 50 having a thickness that may be equal to or less than 2 μm in the vertical direction (Z direction), the ISC 50 may be provided at various locations in the semiconductor package 1. For example, referring to FIG. 1, as a thickness of a build-up layer may range from about 10 to 25 μm and is greater than a thickness of the ISC 50, one or more ISCs 50 may be embedded in the first build-up insulating layer 110 and the second build-up insulating layer 310. One or more ISCs 50 may be placed at a surface layer of the first build-up insulating layer 110 as a land side capacitor (LSC) and a surface layer of the second build-up layer 300 as a die side capacitor (DSC). In addition, one or more ISCs 50 may be provided in a shallow groove or a cavity formed on a surface of the silicon substrate 210. As described in more detail below, shallow grooves having a depth (thickness) of about 3 to 25 μm in the vertical direction (Z direction) may be manufactured in at least one of an upper surface and a lower surface of the silicon substrate 210 during a laser grooving process for manufacturing a through-silicon via 220 in the silicon substrate 210. Thus, when placing an ISC 50 in the shallow grooves of the silicon substrate 210, a separate step of providing a space to include the ISC 50 in the silicon substrate 210 may be omitted and the manufacturing process may be more simplified. However, embodiments are not limited thereto, and a thickness of the one or more ISCs 50 may be adjusted to be the same as a thickness of the silicon substrate 210 in the vertical direction (Z direction).

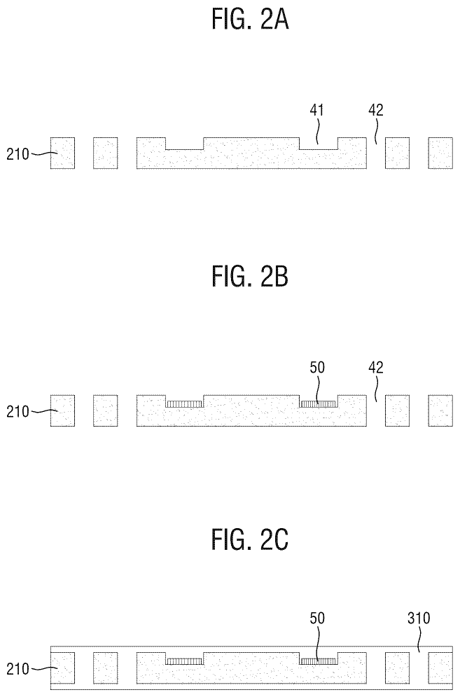

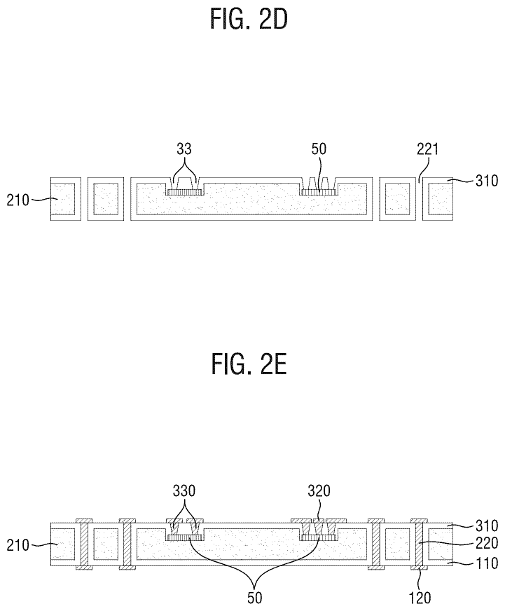

FIGS. 2A through 2F are cross-sectional views illustrating a method of manufacturing a silicon interposer and build-up insulating layers included in a semiconductor package according to one or more embodiments. Descriptions overlapping with previous drawings will be omitted for the sake of brevity and differences will mainly be described. The silicon interposer and the build-up layers manufactured in the method described below may be or correspond to the silicon interposer 200 and the build-up layers 100 and 300 shown in FIG. 1, and thus, the same reference numbers shown in FIG. 1 may be used herebelow.

Referring to FIG. 2A, one or more shallow grooves 41 that have a depth of 3 to 25 μm in the vertical direction (Z direction) are formed through a laser grooving process on a silicon substrate 210. A portion of the shallow grooves 41 may be provided to form through-silicon vias (TSV) 220 and a remaining portion of the shallow grooves 41 may be provided to embed ISCs 50 therein.

Referring to FIG. 2B, one or more ISCs 50 may be provided in the one or more shallow grooves 41 provided in the silicon substrate 210. For example, the ISCs 50 may be embedded in an upper surface and/or a lower surface of the silicon substrate 210. However, embodiments are not limited thereto, and additional ISCs 50 may be embedded inside the silicon substrate 210.

Referring to FIG. 2C, a first build-up insulating layer 110 may be provided to cover the lower surface of the silicon substrate 210 and a second build-up insulating layer 310 may be provided to cover the upper surface of the silicon substrate 210 and the grooves 42. The first build-up insulating layer 110 and the second build-up insulating layer 310 may be integrally formed as a single structure, and may be interchangeably used in the present disclosure. The build-up insulating layer 310 may cover the upper surface of the one or more ISCs 50.

Referring to FIG. 2D, through-silicon tunnels 221 may be formed, for example, by a laser process, wet etching or dry etching. In addition, based on a via-in-via process, trenches 33 are formed on an upper surface of the first build-up insulating layer 110 to expose a portion of upper surfaces of the ISCs 50.

Referring to FIG. 2E, a metal material is filled in the through-silicon tunnels 221 to form through-silicon vias 220, and in the trenches 33 to form second through vias 330. First wiring patterns 120 may be formed on an upper surface of the silicon substrate 210 to contact the through-silicon vias 220 and second through vias 330. The metal material filled in the through-silicon tunnels 221 and the trenches 22 may include a conductive material including, for example, copper (Cu), aluminum (Al), silver (Ag), gold (Au), tungsten (W), titanium (Ti), and a combination thereof. Upper surfaces of the through-silicon vias 220 may be coplanar with the upper surface of the silicon substrate 210 and lower surfaces of the through-silicon via 220 may be coplanar with the lower surface of the silicon substrate 210.

Additional elements, for example, elements as illustrated in FIG. 1 may be provided on the silicon interposer and the build-up insulating layers as illustrated in FIG. 2E.

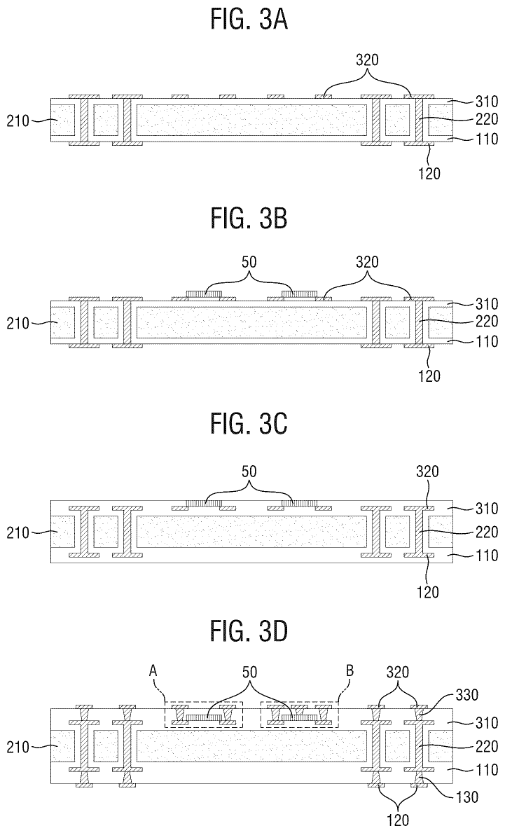

FIGS. 3A through 3D are cross-sectional views illustrating a method of manufacturing a silicon interposer and build-up layers included in a semiconductor package according to one or more other embodiments. Descriptions overlapping with previous drawings will be omitted for the sake of brevity and the differences will mainly be described. The silicon interposer and the build-up layers manufactured in the method described below may be or correspond to the silicon interposer 200 and the build-up layers 100 and 300 shown in FIG. 1, and thus, the same reference numbers shown in FIG. 1 may be used herebelow.

Referring to FIG. 3A, a silicon substrate 210 may include through-silicon vias 220 formed through a laser grooving process to form shallow grooves 41 on the silicon substrate, wet etching process to form through-silicon tunnels, and metallization process of filling the through-silicon tunnels with a metal material, as described above with reference to FIGS. 2A through 2D. Compared to FIG. 2A, one or more shallow grooves 41 to embed one or more ISCs 50 may not be formed. First wiring patterns 120 may be provided on the upper surface and the lower surface of the silicon substrate 210. A portion of the first wiring patterns 120 are provided directly on an upper surface of the through-silicon vias 220 and may provide an electrical path along with the through-silicon vias 220.

Referring to FIG. 3B, one or more ISCs 50 may be provided on at least two adjacent second wiring patterns 320. For example, each of the one or more ISCs 50 may contact upper surfaces of at least two adjacent second wiring patterns 320 that are spaced apart from each other and connect the adjacent second wiring patterns 320.

Referring to FIG. 3C, additional first build-up insulating layer 110 may be laminated on the lower surface of the silicon substrate 210, and the second build-up insulating layer 310 may be laminated on the upper surface of the silicon substrate 210. The second build-up insulating layer 310 may cover the second wiring patterns 320 and the ISCs 50, and the first build-up insulating layer 110 may cover the lower surface of the silicon substrate 210 and the first wiring patterns 120. According to one or more embodiments, in lieu of the first build-up insulating layer 110 and the second build-up insulating layer 310, one or more redistribution layers may be laminated on the upper surface and the lower surface of the silicon substrate 210.

Referring to FIG. 3D, the first through vias 130 may be formed in the first build-up insulating layer 110 and the second through vias 330 may be formed in the second build-up insulating layer 310. One or more second through vias 330 may penetrate one or more second build-up insulating layer 310 and contact an upper surface of the ISC 50, and an opposite side of the one or more second through vias 330 may contact a second wiring pattern 320 as shown in FIG. 1. The first through vias 130 may penetrate one or more first build-up insulating layer 110. In addition, the first through vias 130 may interconnect first wiring patterns 120 provided at different vertical levels, and the second through vias 330 may interconnect second wiring patterns 320 provided at different vertical levels, also as shown in FIG. 1. The first through vias 130 and the second through vias 330 may include, for example, metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and an alloy thereof but is not limited thereto. Additional first build-up insulating layers 110, first wiring patterns 120, and first through vias 130 may be provided, and additional second build-up insulating layers 310, second wiring patterns 320, and second through vias 330 may be provided.

Additional elements, for example, elements as illustrated in FIG. 1 may be provided on the silicon interposer and the build-up layers as illustrated in FIG. 3D.

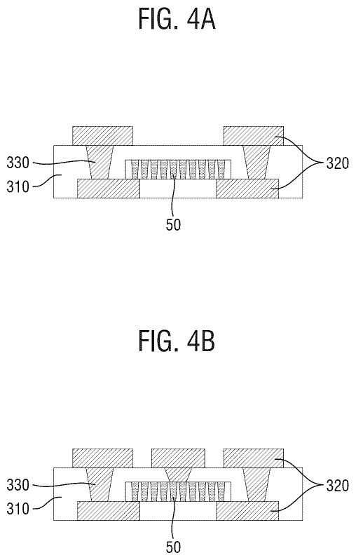

FIG. 4A illustrates an enlarged cross-sectional view of an area A in FIG. 3D and FIG. 4B illustrates an enlarged cross-sectional view of an area B in FIG. 3D.

FIG. 4A illustrates area A of FIG. 3D illustrating an ISC 50 being embedded in a second build-up insulating layer 310. The lower surface of the ISC 50 may contact upper surfaces of two adjacent second wiring patterns 320.

FIG. 4B illustrates the area B of FIG. 3D illustrating an ISC 50 being embedded in a second build-up insulating layer 310. A lower surface of the ISC 50 may contact upper surfaces of adjacent second wiring patterns 320, and an upper surface of the ISC 50 may contact a lower surface of a second via 330.

As illustrated in FIGS. 4A and 4B, the thickness of the ISC 50 which is equal to or less than 2 μm may be less than the thickness of the second build-up insulating layer 310 which may range from 10 to 25 μm in the vertical direction (Z direction). Accordingly, the ISC 50 may be embedded in the build-up insulating layer 310, and the vertical size of the semiconductor package 1 may be reduced.

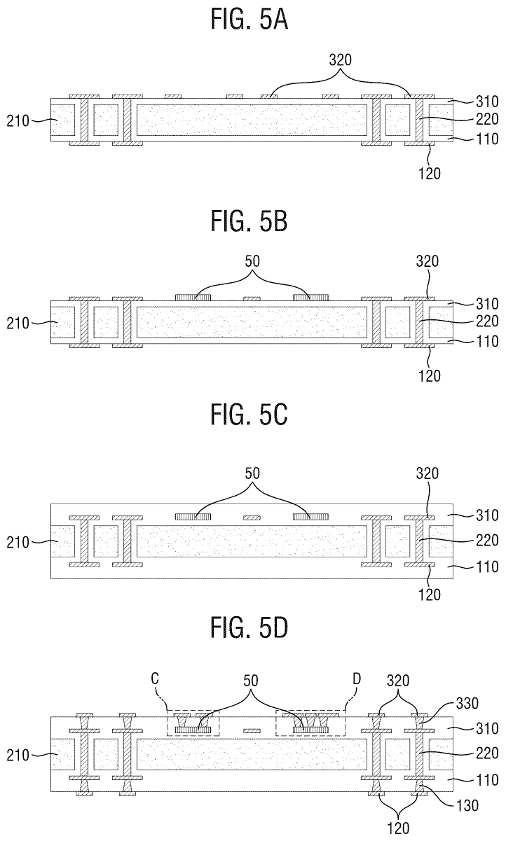

FIGS. 5A through 5D are cross-sectional views illustrating a method of manufacturing a silicon interposer and build-up layers of included in a semiconductor package according to one or more other embodiments. Descriptions overlapping with previous drawings will be omitted for the sake of brevity and the differences will mainly be described. The silicon interposer and the build-up layers manufactured in the method described below may be or correspond to the silicon interposer 200 and the build-up layers 100 and 300 shown in FIG. 1, and thus, the same reference numbers shown in FIG. 1 may be used herebelow.

Referring to FIG. 5A, a silicon substrate 210 may include through-silicon vias 220 formed through a laser grooving process to form shallow grooves on the silicon substrate, wet etching process to form through-silicon tunnels, and metallization process of filling the through-silicon tunnels with a metal material, as described above with reference to FIGS. 2A through 2D. Second wiring patterns 320 may be provided on the upper surface of the silicon substrate 210. A portion of the second wiring patterns 320 are provided directly on an upper surface of the through-silicon vias 220 and may provide an electrical path along with the through-silicon vias 220.

Referring to FIG. 5B, one or more ISCs 50 may be provided directly on the upper surface of the silicon substrate 210 and adjacent to one or more second wiring pattern 320 provided on the upper surface of the silicon substrate 210. For example, a lower surface of the ISC 50 may be coplanar with the upper surface of the silicon substrate 210 and a lower surface of the adjacent second wiring pattern 320. However, embodiments are not limited thereto, and additional ISC 50 may be embedded in the silicon substrate 210 and/or different layers for the first build-up insulating layer 110 and the second build-up insulating layer 310.

Referring to FIG. 5C, the first build-up insulating layer 110 may be laminated on the lower surface of the silicon substrate 210, and the second build-up insulating layer 310 may be laminated on the upper surface of the silicon substrate 210. The second build-up insulating layer 310 may cover the second wiring patterns 320 and the ISCs 50, and the first build-up insulating layer 110 may cover the lower surface of the silicon substrate and the first wiring patterns 120. According to embodiments, in lieu of the first build-up insulating layer 110 and the second build-up insulating layer 310, one or more redistribution layers may be laminated on the upper surface and the lower surface of the silicon substrate 210.

Referring to FIG. 5D, the first through vias 130 may be formed in the first build-up insulating layer 110 and the second through vias 330 may be formed in the second build-up insulating layer 310. The first through vias 130 may penetrate one or more first build-up insulating layer 110 and the second through vias 330 may penetrate one or more second build-up insulating layers 310. The first through vias 130 may interconnect first wiring patterns 120 provided at different vertical levels, and the second through vias 330 may interconnect second wiring patterns 320 provided at different vertical levels, as shown in FIG. 1. In addition, one or more second through vias 330 may be provided to contact the one or more ISCs 50. For example, a lower surface of the one or more second through vias 330 may directly contact an upper surface of the ISC 50. The first through vias 130 and the second through vias 330 may include, for example, metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and an alloy thereof but is not limited thereto. Additional first build-up insulating layers 110, first wiring patterns 120, and first through vias 130 may be provided, and additional second build-up insulating layers 310, second wiring patterns 320, and second through vias 330 may be provided.

Additional elements, for example, elements as illustrated in FIG. 1 may be provided on the silicon interposer and the build-up layers as illustrated in FIG. 5D.

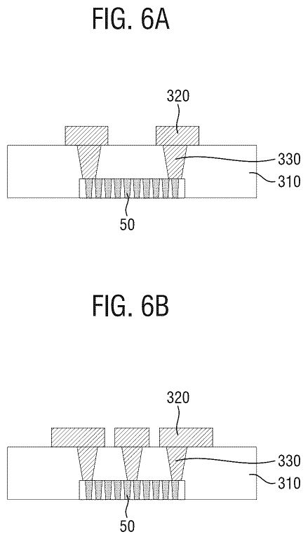

FIG. 6A illustrates an enlarged cross-sectional view of an area C in FIG. 5D and FIG. 6B illustrates an enlarged cross-sectional view of an area D in FIG. 5D.

FIG. 6A illustrates the area C of FIG. 5D illustrating an ISC 50 being embedded in a second build-up insulating layer 310 and connecting adjacent second through vias 330. An upper surface of the ISC 50 may contact lower surfaces of two adjacent second through vias 330 and a lower surface of the ISC 50 may contact the silicon substrate 210.

FIG. 6B illustrates the area D of FIG. 5D illustrating an ISC 50 being embedded in a second build-up insulating layer 310 and connecting adjacent second through vias 330. An upper surface of the ISC 50 may contact lower surfaces of three adjacent second through vias 330 and a lower surface of the ISC 50 may contact the silicon substrate 210. As illustrated in FIGS. 6A and 6B, the thickness of the ISC 50 which is equal to or less than 2 μm may be less than the thickness of the second build-up insulating layer 310 which may range from 10 to 25 μm in the vertical direction (Z direction). Accordingly, as the ISC 50 may be embedded in the build-up insulating layer 310, the vertical size of the semiconductor package 1 may be reduced.

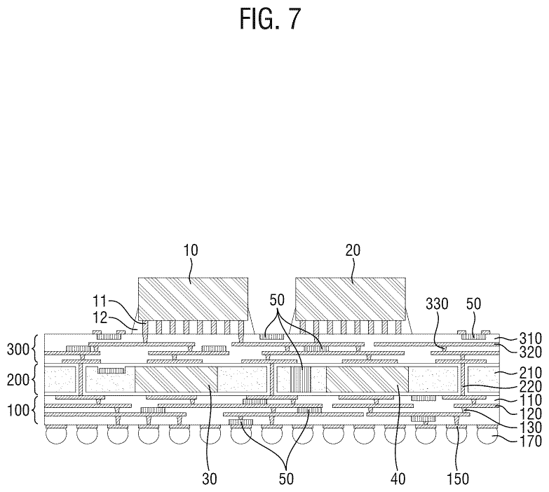

FIG. 7 illustrates a semiconductor package according to one or more other embodiments. Descriptions overlapping with previous drawings will be omitted for the sake of brevity and the differences will mainly be described.

Referring to FIG. 7, in comparison with the semiconductor package 1 illustrated in FIG. 1, in addition to the first semiconductor chip 10 and the second semiconductor chip 20 provided on an upper surface of the second build-up layer 300, the semiconductor package 2 may include a third semiconductor chip 30 and a fourth semiconductor chip 40 embedded in the silicon substrate 210. For example, the third semiconductor chip 30 and the fourth semiconductor chip 40 may be provided in a cavity in the silicon substrate 210 adjacent to the through-silicon vias 220. The upper surface of the third semiconductor chip 30 and an upper surface of the fourth semiconductor chip 40 may be coplanar with an upper surface of the silicon substrate 210. Connection pads may be provided on a surface of the third semiconductor chip 30 and a surface of the fourth semiconductor chip 40. One or more of first through vias 130 and second through vias 330 may be connected to the connection pads of the third semiconductor chip 30 and a surface of the fourth semiconductor chip 40. The first semiconductor chip 10 and the second semiconductor chip 20 may be, for example, high bandwidth memory (HBM) chips and the third semiconductor chip 30 and the fourth semiconductor chip 40 may be system-on-chip (SOC). However, embodiments are not limited thereto, and semiconductor chips other than an SOC or an HBM, such as, for example, a logic chip such as a central processor (CPU), a graphics processor (GPU), a field programmable gate array (FPGA), a digital signal processor (DSP), an application-specific integrated circuit (ASIC) or a memory chip such as a dynamic random access memory (DRAM) chip and a NAND chip, may be provided.

As illustrated in FIG. 7, ISCs 50 may be provided at various locations in the semiconductor package 2. For example, as a thickness of a first build-up layer 100 and a second build-up layer 300 may range from about 10 to 25 μm, one or more ISCs 50 may be placed at a surface layer of the first build-up insulating layer 110 as a land side capacitor (LSC) and a surface layer of the second build-up layer 300 as a die side capacitor (DSC). In addition, one or more ISCs 50 may be provided in a shallow groove or a cavity formed on a surface of the silicon substrate 210. A thickness of each of the one or more ISCs 50 embedded in the silicon substrate 210 may be less than or equal to the thickness of the silicon substrate 210 in the vertical direction (Z direction).

Referring to FIG. 7, as the ISCs 50 may be embedded in the first build-up insulating layer 110, the second build-up insulating layer 310, and the silicon substrate 210, the ISCs 50 may be provided closer to the first semiconductor chip 10, the second semiconductor chip 20, the third semiconductor chip 30, and the fourth semiconductor chip 40, compared to a semiconductor package including, for example, a multilayer ceramic capacitor (MLCC). Thus, the vertical size of the semiconductor package 2 may be reduced and the impedance of the power distribution network (PDN) for multiple frequency ranges, in particular, relatively high frequency ranges may be lowered and the performance of the semiconductor package 2 may be improved.

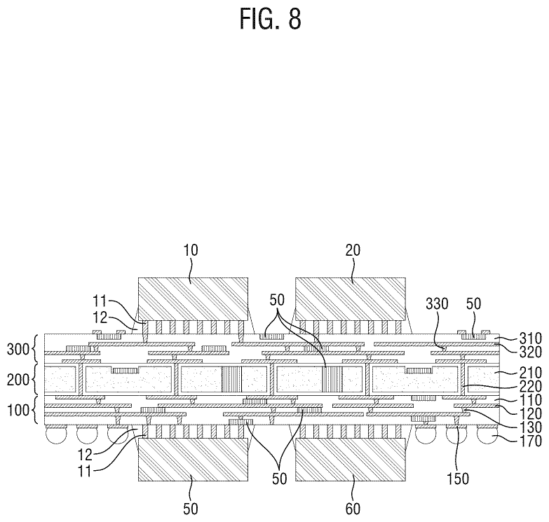

FIG. 8 illustrates a semiconductor package according to one or more other embodiments. Descriptions overlapping with previous drawings will be omitted for the sake of brevity and the differences will mainly be described.

Referring to FIG. 8, in comparison with the semiconductor package 1 illustrated in FIG. 1, in addition to the first semiconductor chip 10 and the second semiconductor chip 20 provided on an upper surface of the second build-up layer 300, the semiconductor package 3 may include a fifth semiconductor chip 50 and a sixth semiconductor chip 60 provided on a lower surface of the first build-up layer 100.

As illustrated in FIG. 8, ISCs 50 may be provided at various locations in the semiconductor package 3. For example, as a thickness of a first build-up layer 100 and a second build-up layer 300 may range from about 10 to 25 μm, one or more ISC 50 may be placed at a surface layer of the first build-up insulating layer 110 as a land side capacitor (LSC) and a surface layer of the second build-up layer 300 as a die side capacitor (DSC). In addition, one or more ISCs 50 may be provided in a shallow groove or a cavity formed on a surface of the silicon substrate 210. A thickness of each of the one or more ISCs 50 embedded in the silicon substrate 210 may be less than or equal to the thickness of the silicon substrate 210 in the vertical direction (Z direction).

Referring to FIG. 8, as the ISCs 50 may be embedded in the first build-up insulating layer 110, the second build-up insulating layer 310, and the silicon substrate 210, the ISCs 50 may be provided closer to the first semiconductor chip 10, the second semiconductor chip 20, the third semiconductor chip 30, and the fourth semiconductor chip 40, compared to a semiconductor package including, for example, a multilayer ceramic capacitor (MLCC). Thus, the vertical size of the semiconductor package 3 may be reduced and the impedance of the power distribution network (PDN) for multiple frequency ranges, in particular, relatively high frequency ranges may be lowered and the performance of the semiconductor package 3 may be improved.

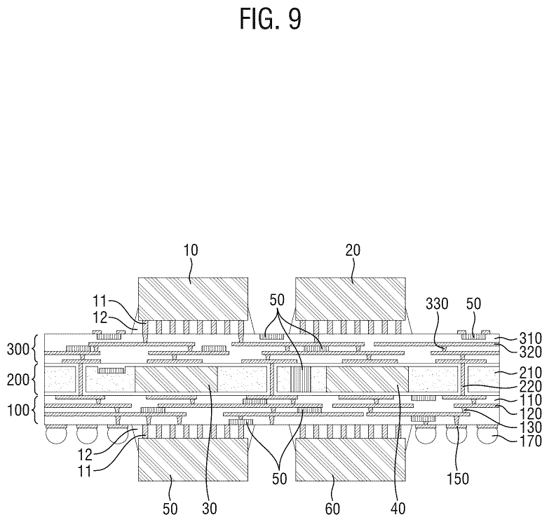

FIG. 9 illustrates a semiconductor package according to one or more other embodiments. Descriptions overlapping with previous drawings will be omitted for the sake of brevity and the differences will mainly be described.

Referring to FIG. 9, in comparison with the semiconductor package 3 illustrated in FIG. 8, in addition to the first semiconductor chip 10, the second semiconductor chip 20, the semiconductor package 4 may include a third semiconductor chip 30 and a fourth semiconductor chip 40 embedded in the silicon substrate 210 similar to those illustrated in FIG. 7 and a fifth semiconductor chip 50 and a sixth semiconductor chip 60 on a lower surface of the first build-up layer 100 similar to those illustrated in FIG. 8. For example, the third semiconductor chip 30 and the fourth semiconductor chip 40 may be provided in a cavity in the silicon substrate 210 adjacent to the through-silicon vias 220. The upper surface of the third semiconductor chip 30 and an upper surface of the fourth semiconductor chip 40 may be coplanar with an upper surface of the silicon substrate 210. Connection pads may be provided on a surface of the third semiconductor chip 30 and a surface of the fourth semiconductor chip 40. One or more of first through vias 130 and second through vias 330 may be connected to the connection pads of the third semiconductor chip 30 and a surface of the fourth semiconductor chip 40.

As illustrated in FIG. 9, one or more ISCs 50 may be provided at various locations in the semiconductor package 4. For example, as a thickness of a first build-up layer 100 and a second build-up layer 300 may range from about 10 to 25 μm, the one or more ISCs 50 may be placed at a surface layer of the first build-up insulating layer 110 as a land side capacitor (LSC) and a surface layer of the second build-up layer 300 as a die side capacitor (DSC). In addition, the one or more ISCs 50 may be provided in a shallow groove or a cavity formed on a surface of the silicon substrate 210. A thickness of each of the one or more ISCs 50 embedded in the silicon substrate 210 may be less than or equal to the thickness of the silicon substrate 210 in the vertical direction (Z direction).

Referring to FIG. 9, as the ISCs 50 may be embedded in the first build-up insulating layer 110, the second build-up insulating layer 310, and the silicon substrate 210, the ISCs 50 may be provided closer to the first semiconductor chip 10, the second semiconductor chip 20, the third semiconductor chip 30, the fourth semiconductor chip 40, the fifth semiconductor chip 50, and the sixth semiconductor chip 60, compared to a semiconductor package including, for example, a multilayer ceramic capacitor (MLCC). Thus, the vertical size of the semiconductor package 4 may be reduced and the impedance of the power distribution network (PDN) for multiple frequency ranges, in particular, relatively high frequency ranges may be lowered and the performance of the semiconductor package 3 may be improved.

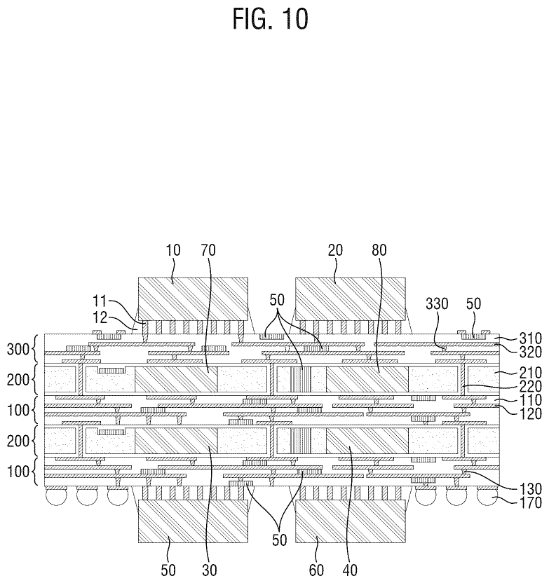

FIG. 10 illustrates a semiconductor package according to one or more other embodiments. Descriptions overlapping with previous drawings will be omitted for the sake of brevity and the differences will mainly be described.

Referring to FIG. 10, in comparison with the semiconductor package 4 illustrated in FIG. 9, in addition to the first semiconductor chip 10, the second semiconductor chip 20, the third semiconductor chip 30, the fourth semiconductor chip 40, the fifth semiconductor chip 50, and the sixth semiconductor chip 60, the semiconductor package 5 may include at least one additional silicon substrate 210′ stack on the silicon substrate 210. In addition, similar to the third semiconductor chip 30 and the fourth semiconductor chip 40, a seventh semiconductor chip 70 and an eighth semiconductor chip 80 may be embedded in the silicon substrate 210′.

As illustrated in FIG. 10, ISCs 50 may be provided at various locations in the semiconductor package 5. For example, as a thickness of a first build-up layer 100 and a second build-up layer 300 may range from about 10 to 25 μm, one or more ISCs 50 may be placed at a surface layer of the first build-up insulating layer 110 as a land side capacitor (LSC) and a surface layer of the second build-up layer 300 as a die side capacitor (DSC). In addition, the one or more ISCs 50 may be provided in a shallow groove or a cavity formed on a surface of the silicon substrate 210. A thickness of each of the one or more ISCs 50 embedded in the silicon substrate 210 may be less than or equal to the thickness of the silicon substrate 210 in the vertical direction (Z direction).

Referring to FIG. 10, as the ISCs 50 may be embedded in the first build-up insulating layer 110, the second build-up insulating layer 310, and the silicon substrates 210 and 210′, the ISCs 50 may be provided closer to the first semiconductor chip 10, the second semiconductor chip 20, the third semiconductor chip 30, the fourth semiconductor chip 40, the fifth semiconductor chip 50, the sixth semiconductor chip 60, the seventh semiconductor chip 70, and the eighth semiconductor chip 80, compared to a semiconductor package including, for example, a multilayer ceramic capacitor (MLCC). Thus, the vertical size of the semiconductor package 5 may be reduced and the impedance of the power distribution network (PDN) for multiple frequency ranges, in particular, relatively high frequency ranges may be lowered and the performance of the semiconductor package 5 may be improved.

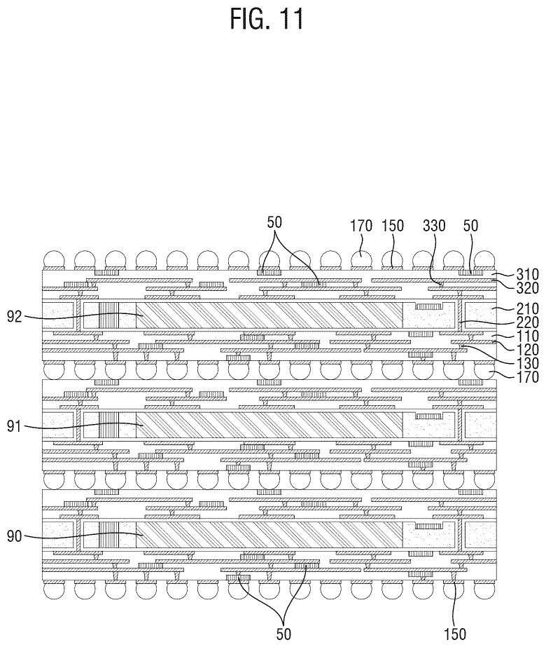

FIG. 11 illustrates a semiconductor package according to one or more other embodiments. Descriptions overlapping with previous drawings will be omitted for the sake of brevity and the differences will mainly be described.

Referring to FIG. 10, the semiconductor package 6 may be a three-dimensional (3D) stacked semiconductor package including silicon interposers 200 that are stacked on top of each other. For example, FIG. 10 illustrates three silicon interposers 200 that are stacked, but embodiments are not limited thereto. Each of the silicon interposers 200 may include semiconductor chips 90, 91, and 92 embedded therein. The silicon interposer 200 may be the same as that described with reference to FIG. 1. The silicon interposers 200 may be connected to each other by external connection terminals 170. The semiconductor chips 90, 91, and 92 may each be a dynamic random access memory (DRAM) chip, a static random access memory (SRAM) chip, a logic die, or so on., but embodiments are not limited thereto.

As illustrated in FIG. 10, ISCs 50 may be provided at various locations in the semiconductor package 5. For example, as a thickness of a first build-up layer 100 and a second build-up layer 300 may range from about 10 to 25 μm in each of the silicon interposers 200, one or more ISCs 50 may be placed at a surface layer of the first build-up insulating layer 110 as a land side capacitor (LSC) and a surface layer of the second build-up layer 300 as a die side capacitor (DSC). In addition, the one or more ISCs 50 may be provided in one or more shallow grooves or cavities formed on a surface of the silicon substrate 210. A thickness of the one or more ISCs 50 embedded in the silicon substrate 210 may be less than or equal to the thickness of the silicon substrate 210 in the vertical direction (Z direction).

Referring to FIG. 10, as the ISCs 50 may be embedded in the first build-up insulating layer 110, the second build-up insulating layer 310, and the silicon substrates 210 and 210′, the ISCs 50 may be provided closer to the semiconductor chips 90, 91, and 92, compared to a semiconductor package including, for example, a multilayer ceramic capacitor (MLCC). Thus, the vertical size of the semiconductor package 6 may be reduced and the impedance of the power distribution network (PDN) for multiple frequency ranges, in particular, relatively high frequency ranges may be lowered and the performance of the semiconductor package 6 may be improved.

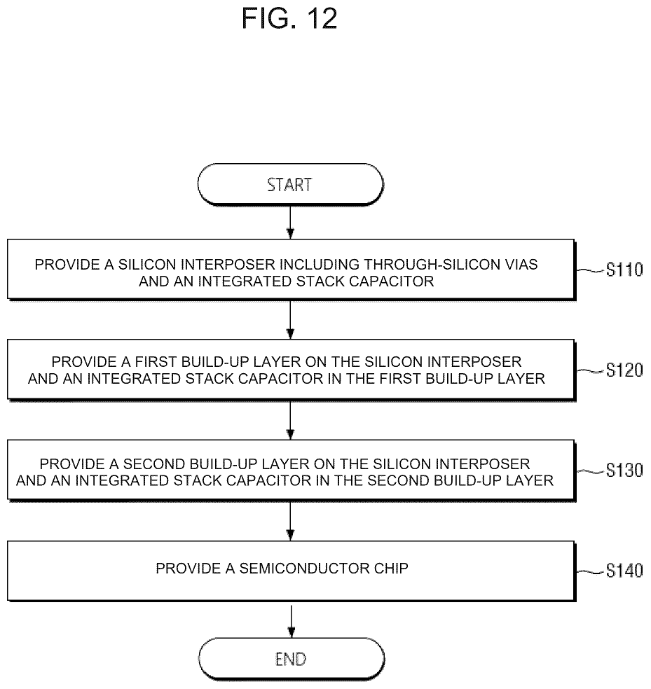

FIG. 12 illustrates a flowchart of manufacturing a semiconductor package according to one or more embodiments.

In operation S110, a silicon interposer including a silicon substrate and through-silicon vias vertically penetrating the silicon substrate is formed. The silicon substrate is laser processed to form shallow grooves and/or cavities on an upper surface and a lower surface of the silicon substrate, and a portion of the shallow grooves and/or cavities are wet etched or dry etched to form through-silicon tunnels penetrating the silicon substrate. The through-silicon tunnels are filled with metal material to form through-silicon vias. The metal material may include a conductive material including, for example, copper (Cu), aluminum (Al), silver (Ag), gold (Au), tungsten (W), titanium (Ti), and a combination thereof, but embodiments are not limited thereto. One or more ISCs may be embedded in the one or more shallow grooves and/or cavities of the silicon substrate.

In operation S120, a first build-up layer is formed on the lower surface of the silicon interposer. A first build-up insulating layer is laminated on the lower surface of the silicon substrate and the one or more ISCs, and first wiring patterns are formed on first build-up insulating layer. First through vias are formed to penetrate the first build-up insulating layer, and may interconnect first wiring patterns provided at different vertical levels and connect one or more first wiring patterns to the ISC. Additional layers of the first build-up insulating layers with first wiring patterns and first through vias may be formed on a lower surface of the first build-up insulating layer. In addition, one or more ISCs may be embedded in one of the first build-up insulating layers or different levels of the first build-up insulating layers and connected to at least one of a first via and a first wiring pattern. A passivation layer may be formed on a lowermost first build-up insulating layer. An under bump metallurgy (UBM) layer and a conductive layer may be formed, and an external connection terminal may be formed on the conductive layer to connect the semiconductor package to an external device.

In operation S130, a second build-up layer is formed on the upper surface of the silicon interposer. A second build-up insulating layer is laminated on the upper surface of the silicon substrate and the one or more ISCs embedded in the silicon substrate, and second wiring patterns are formed on second build-up insulating layer. Second through vias are formed to penetrate the second build-up insulating layer, and may interconnect second wiring patterns provided at different vertical levels. Additional layers of the second build-up insulating layers with second wiring patterns and second through vias may be formed on an upper surface of the second build-up insulating layer. In addition, one or more ISCs may be embedded in one of the second build-up insulating layers or different levels of the second build-up insulating layers and connected to at least one of a second via and a second wiring pattern. At operation S140, one or more semiconductor chips may be provided. For example, a semiconductor chip may be provided on the lower surface of the first build-up layer and the upper surface of the second build-up layer. Connection members may be formed to connect the semiconductor chip with first and second wiring patterns included in the first and second build-up layers. An underfill layer may fill spaces between the connection members. The semiconductor chip may be, for example, a logic chip such as a CPU, a GPU, a FPGA, a DSP, an ASIC, an SOC chip, an HBM chip, a DRAM chip, an SRAM chip, a NAND chip, and so on, however, embodiments are not limited thereto. According to one or more other embodiments, semiconductor chips may also be provided in a cavity formed in the silicon substrate prior to forming the first build-up layer and the second build-up layer. In addition, multiple silicon interposers may be stacked on top of each other, and directly connected to each other or connected to each other through external connection terminals therebetween.

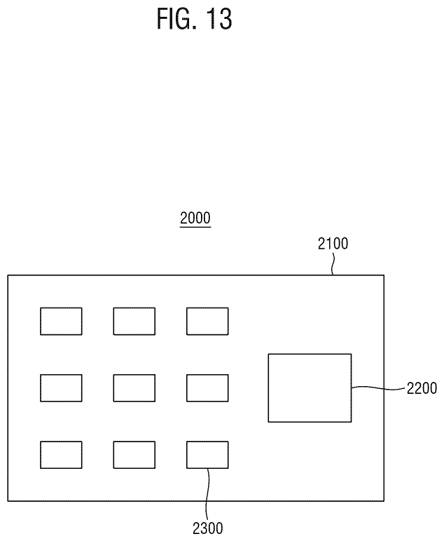

FIG. 13 illustrates a semiconductor package architecture that may incorporate the semiconductor packages according to one or more embodiments.

Referring to FIG. 13, a semiconductor package architecture 2000 according to one or more embodiments may include a processor 2200 and semiconductor devices 2300 that are mounted on a substrate 2100. The processor 2200 and/or the semiconductor devices 2300 may include one or more of semiconductor packages described in the above embodiments.

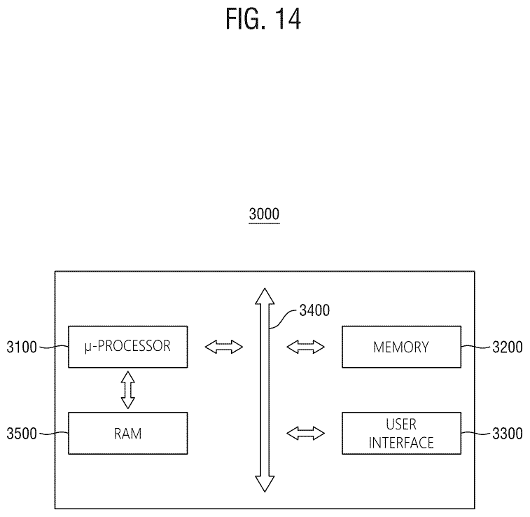

FIG. 14 illustrates a schematic block diagram of an electronic system according to one or more embodiments.

Referring to FIG. 14, an electronic system 3000 in accordance with one or more embodiments may include a microprocessor 3100, a memory 3200, and a user interface 3300 that perform data communication using a bus 3400. The microprocessor 3100 may include a central processing unit (CPU) or an application processor (AP). The electronic system 3000 may further include a random access memory (RAM) 3500 in direct communication with the microprocessor 3100. The microprocessor 3100 and/or the RAM 3500 may be implemented in a single module or package. The user interface 3300 may be used to input data to the electronic system 3000, or output data from the electronic system 3000. For example, the user interface 3300 may include a keyboard, a touch pad, a touch screen, a mouse, a scanner, a voice detector, a liquid crystal display (LCD), a micro light-emitting device (LED), an organic light-emitting diode (OLED) device, an active-matrix light-emitting diode (AMOLED) device, a printer, a lighting, or various other input/output devices without limitation. The memory 3200 may store operational codes of the microprocessor 3100, data processed by the microprocessor 3100, or data received from an external device. The memory 3200 may include a memory controller, a hard disk, or a solid state drive (SSD).

At least the microprocessor 3100, the memory 3200 and/or the RAM 3500 in the electronic system 3000 may include semiconductor packages as described in the above embodiments.

It should be understood that embodiments described herein should be considered in a descriptive sense only and not for purposes of limitation. Descriptions of features or aspects within each embodiment should typically be considered as available for other similar features or aspects in other embodiments.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor package comprising:
a silicon substrate comprising a through-silicon via;
a first build-up layer on a first surface of the silicon substrate;
a second build-up layer on a second surface of the silicon substrate; and
at least one capacitor included in at least one of the silicon substrate, the first build-up layer, and the second build-up layer.

2. The semiconductor package according to claim 1, wherein the first build-up layer comprises:
a first build-up insulating layer;
a plurality of first wiring patterns; and
a first through vias connecting the plurality of first wiring patterns, and
wherein the second build-up layer comprises:
a second build-up insulating layer;
a plurality of second wiring patterns; and
a second through vias connecting the plurality of second wiring patterns.

3. The semiconductor package according to claim 2, wherein a capacitor among the at least one capacitor is on at least one of a first surface of the first build-up layer and a second surface of the second build-up layer.

4. The semiconductor package according to claim 2, wherein a capacitor among the at least one capacitor is included in at least one of the first build-up insulating layer and the second build-up insulating layer, and
wherein the capacitor is connected to at least one of the plurality of first wiring patterns, the first through via, the plurality of second wiring patterns, and the second through via.

5. The semiconductor package according to claim 2, wherein a capacitor among the at least one capacitor is included in the second build-up insulating layer, and
wherein the capacitor is on second surfaces of two adjacent second wiring patterns among the plurality of second wiring patterns.

6. The semiconductor package according to claim 2, wherein a capacitor among the at least one capacitor is included in the second build-up insulating layer, and
wherein the capacitor is directly on the second surface of the silicon substrate.

7. The semiconductor package according to claim 1, wherein the silicon substrate comprises a groove on at least one of the first surface of the silicon substrate and the second surface of the silicon substrate, and
wherein a capacitor among the at least one capacitor is provided in the groove.

8. The semiconductor package according to claim 1, further comprising:
a semiconductor chip on at least one of a first surface of the first build-up layer and a second surface of the second build-up layer; and
a connection member between the semiconductor chip and at least one of the first surface of the first build-up layer and the second surface of the second build-up layer,
wherein the connection member contacts a capacitor among the at least one capacitor.

9. The semiconductor package according to claim 8, further comprising:
a second semiconductor chip included in the silicon substrate,
wherein another capacitor among the at least one capacitor is included in the silicon substrate adjacent to the second semiconductor chip.

10. The semiconductor package according to claim 8, further comprising:
a second silicon substrate comprising a through via,
wherein a fourth semiconductor chip is included in the second silicon substrate, and
wherein another capacitor among the at least one capacitor is included in the second silicon substrate.

11. The semiconductor package according to claim 1, further comprising:
a third semiconductor chip included in the silicon substrate,
wherein a capacitor among the at least one capacitor is included in the silicon substrate adjacent to the third semiconductor chip.

12. The semiconductor package according to claim 11, wherein a second surface of the capacitor is connected to a first surface of the second through via.

13. The semiconductor package according to claim 1, wherein a capacitor among the at least one capacitor is included in the silicon substrate, and
wherein a thickness of the capacitor is less than or equal to a thickness of the silicon substrate in a vertical direction.

14. The semiconductor package according to claim 1, wherein a thickness of each of the at least one capacitor in a vertical direction is less than or equal to 2 μm.

15. A method of manufacturing a semiconductor package, the method comprising:
providing a silicon substrate comprising through-silicon via;
providing a first build-up layer on a first surface of the silicon substrate;
providing a second build-up layer on a second surface of the silicon substrate;
providing a capacitor in at least one of the silicon substrate, the first build-up layer, and the second build-up layer; and
providing a semiconductor chip.

16. The method of claim 15, further comprising:
forming a groove on at least one of the second surface of the silicon substrate and the first surface of the silicon substrate,
wherein the providing the capacitor comprises providing the capacitor in the groove.

17. The method of claim 15, wherein providing the second build-up layer comprises providing a second build-up insulating layer, a plurality of second wiring patterns, and second through via, and
wherein providing the capacitor comprises providing the capacitor in the second build-up insulating layer.

18. The method of claim 15, wherein providing the second build-up layer comprises providing a second build-up insulating layer, a plurality of second wiring patterns, and second through via, and
wherein providing the capacitor comprises providing the capacitor in the second build-up insulating layer and directly on the second surface of the silicon substrate.

19. The method of claim 15, wherein the providing the semiconductor chip comprises provided the semiconductor chip in at least one of the silicon substrate, a first surface of the first build-up layer, and a second surface of the second build-up layer,
wherein the semiconductor chip overlaps the capacitor in a vertical direction.

20. An electronic system comprising:
at least one memory configured to store computer-readable instructions and a plurality of data; and
at least one processor configured to execute the computer-readable instructions and implement a plurality of computing operations using the plurality of data,
wherein the at least one processor comprises a semiconductor package comprising:
a silicon substrate comprising a through-silicon via;
a first build-up layer on a first surface of the silicon substrate;
a second build-up layer on a second surface of the silicon substrate; and
at least one capacitor included in at least one of the silicon substrate, the first build-up layer, and the second build-up layer.
